(19) United States
(12) Patent Application Publication
(10) Pub. No.: US 2006/0290370 A1
(43) Pub. Date: Dec. 28, 2006

(54) TEMPERATURE CONTROL IN IC SOCKETS

(75) Inventor: Christopher A. Lopez, Phoenix, AZ (US)

Correspondence Address: MARGER JOHNSON & MCCOLLOM, P.C., 210 SW MORRISON STREET, SUITE 400, PORTLAND, OR, 97204, US

(73) Assignee: WELLS-CTI, LLC, AN OREGON LIMITED LIABILITY COMPANY, Vancouver, WA (US)

(21) Appl. No.: 11/459,288

(22) Filed: Jul. 21, 2006

Related U.S. Application Data
(63) Continuation-in-part of application No. 10/920,531, filed on Aug. 17, 2004, now Pat. No. 7,123,037.
(60) Provisional application No. 60/703,774, filed on Jul. 28, 2005.
(60) Provisional application No. 60/548,303, filed on Feb. 27, 2004.

(51) Int. Cl. G01R 31/26

(52) U.S. Cl. 324/765

(57) ABSTRACT

A system and method are provided which provides more accurate temperature control of integrated circuits. A system for testing integrated circuit (IC) packages comprises a plurality of IC testing socket bases arranged on a testing board and configured to receive a plurality of IC packages. A plurality of IC testing socket lids are arranged to attach to the testing board. Each IC testing socket lid comprises a temperature sensor to thermally contact the IC package and measure a surface temperature of the IC package, a heater or cooler to directly contact the IC package, and an electronic controller to receive signals from the temperature sensor. The electronic controller is programmed to change the temperature of the heater or cooler responsive to the measured surface temperature of the IC package. A plurality of cooling devices individually removes heat generated by the plurality of IC packages. The electronic controller in each IC testing socket lid is further programmed to control a corresponding cooling device to maintain the surface temperature of the plurality of IC packages within a desired temperature range.

### RELATED APPLICATION DATA

This application claims priority from U.S. Ser. No. 60/703,774, filed on Jul. 28, 2005, the contents of which are herein incorporated by reference in their entirety. This application is a continuation-in-part of commonly assigned and copending U.S. Ser. No. 10/920,531, entitled “Integrated Circuit Temperature Sensing Device and Method,” filed on Aug. 17, 2004 and claims priority from U.S. Ser. No. 60/548,303, filed on Feb. 27, 2004, the contents of which are herein incorporated by reference in their entirety.

### TECHNICAL FIELD

This invention relates to integrated circuit testing sockets and, more particularly, to temperature control of integrated circuits in an integrated circuit testing and/or burn-in socket.

### BACKGROUND OF THE INVENTION

Integrated circuit (IC) packages must be tested after their manufacture, normally at elevated temperatures, which is typically a burn-in process. During that process, it is often necessary to control the temperature of ICs, sensors, and other elements. Techniques for doing so have been widely practiced for many years. The system normally consists of a heater (or cooler), a temperature sensor, and a comparator which applies energy to a heater in proportion to the difference in voltage measured by the temperature sensor as compared to a reference voltage. The energy is applied in the proper direction to cause the difference voltage to be reduced. Temperature control modules and temperature sensors of many types are widely sold for these purposes. A typical application is the control of the temperature of ICs for a burn-in process because of the temperature sensitivity of the ICs.

To achieve more accurate testing results, it is desirable to control the temperature of each individual IC being tested. Within a testing oven without individual temperature control, the actual temperature of each IC can vary due to different rates of convection, heat dissipation, or radiation within the oven. Individual temperature control can be achieved by sensing the temperature of each IC, varying the heat directed to each IC through the use of individual heaters, and more precisely controlling the rate of convection.

FIG. 1 is a simplified plan view of a system of burn-in boards 28 within a testing or burn-in chamber 10. In a conventional burn-in chamber 10, temperature control has typically included the application of an air flow 20 generally across numerous sockets 22 located on the burn-in boards 28. As shown in FIG. 1, the air flow 20 in burn-in chamber 10 cools the sockets 22 on the burn-in boards 28 allowing for tighter control of the temperature of the ICs in the sockets 22. Individually determined amounts of heat are then applied to each individual IC. The air flow 20 is typically generated by a single source such as a single fan 24. Even if multiple fans are used, the air flow 20 is generalized across all of the sockets 22 creating extremely non-uniform air flow 26. The non-uniform nature of the air flow 26 makes it difficult, if not impossible, to accurately predict the convective effect of the air flow 26 on any given socket 22 on the burn-in boards 28. Thus, the overall air flow 20 must be increased and/or maintained at a high enough rate to ensure that the hottest IC is properly cooled. Consequently, cooler ICs receive more air flow 26 than they necessarily need to accomplish the burning-in or testing. As a result, the individual heaters of the cooler ICs must then increase power consumption to compensate for the over-cooling.

Three examples of sensing and heating individual ICs can be found in U.S. Pat. No. 5,164,661 issued to Jones, U.S. Pat. No. 5,911,897 issued to Hamilton, and U.S. Pat. No. 7,042,240 (“the '240 patent”) issued to Lopez et al. Both Jones and Hamilton disclose a testing socket with a sensor in direct contact with an IC that senses the case temperature of the IC. The '240 patent, which is owned by the assignee of the present application and wholly incorporated by reference herein, discloses another structure and method of sensing and heating individual ICs utilizing localized processing and control of the information and heating. To help cool the device under test in the socket, all three of these examples utilize a generalized air flow 20, as shown in FIG. 1, which can result in unnecessarily high air flow over a cooler IC that, in turn, can result in unnecessarily higher power consumption by the individual heater.

Thus, it would be advantageous to better control the convective cooling of a test/burn-in socket to reduce overall power consumption of the testing-/burning-in system.

### SUMMARY OF THE INVENTION

One aspect of the invention is a system for testing integrated circuit (IC) packages which comprises a plurality of IC testing socket bases arranged on a testing board and configured to receive a plurality of IC packages. A plurality of IC testing socket lids is attached to the testing board. Each IC testing socket lid comprises a temperature sensor to thermally contact the IC package and measure a surface temperature of the IC package, a heater or cooler to directly contact the IC package, and an electronic controller to receive signals from the temperature sensor. The electronic controller is programmed to change the temperature of the heater or cooler responsive to the measured surface temperature of the IC package. The system further comprises a plurality of cooling devices to individually remove heat generated by the plurality of IC packages. The electronic controller in each IC testing socket lid is further programmed to control a corresponding cooling device to maintain the surface temperature of the plurality of IC packages within a desired temperature range.

Another aspect of the invention is a method of controlling the temperature of an integrated circuit (IC) package during one or more of testing, burning-in and programming of the IC package. The method includes sensing a temperature of the IC package with a temperature sensor in thermal contact with the IC package, the temperature sensor being located in an IC socket lid. The method also includes processing data from the temperature sensor in an electronic controller located in the IC socket lid and controlling the temperature of the IC package with a heater or cooler located in the IC socket lid responsive to a signal from the electronic controller. The method further includes removing heat generated by the IC package to maintain the temperature of the IC package within a desired temperature range with a cooling device.

### BRIEF DESCRIPTION OF THE DRAWINGS

The above and other features and advantages of embodiments of the invention will become readily apparent by reference to the following detailed description when considered in conjunction with the accompanying drawings.

FIG. 1 is a block plan view of a typical system of multiple testing sockets on burn-in boards in a burn-in chamber.

FIG. 2 is a block plan view of a system of multiple testing sockets on burn-in boards in a burn-in chamber according to an embodiment of the invention.

FIG. 3 is an exploded side elevation schematic of a testing socket on a burn-in board in FIG. 2.

### DETAILED DESCRIPTION

As will be apparent to those skilled in the art from the following disclosure, the invention as described herein may be embodied in many different forms and should not be construed as limited to the specific embodiments set forth herein. Rather, these embodiments are provided so that this disclosure will fully convey the principles of the invention to those skilled in the art.

More precise control of the temperature of an integrated circuit (IC) being tested, programmed, or burned-in may be desired. In this description, the processes of testing, programming and burning-in will be referred to simply as testing. Integrated circuits include individual dies and IC packages and the term integrated circuit used throughout this specification encompasses all forms of integrated circuits. A testing socket designed to receive an IC for testing can be used during testing or in applications where accurate temperature control of the IC is desired. It should be appreciated that IC testing using testing sockets is merely one example in which inventive principles of the invention can be applied. The invention can also be applied to devices that are mounted directly to a printed circuit board (PCB).

Embodiments of the invention achieve this precise temperature control of ICs by controlling convection, the transfer of energy via a moving fluid (liquids, vapor, or gas). The fluid can heat or cool a surface with which it comes in contact, depending on the fluid temperature relative to the surface. Thus, one can achieve temperature control using the following equation:

$$Δ T = \frac{Q}{h * A} ,$$

where ΔT is the change in temperature (between the fluid and the surface), Q is the heat generated by the IC 40 (the amount of heat transferred), A is the surface area of the IC 40, and h is the convection coefficient. The convection coefficient h is a measure of how effective the fluid is at carrying heat to and away from the surface. The convection coefficient h is dependent of factors such as the fluid density, velocity, and viscosity. Generally, fluids with higher velocity and/or higher density have greater convection coefficient h. The fluid or cooling medium is typically air but can include other types of cooling media. For a given IC 40 under test, both Q and A remain constant. The convection coefficient h remains variable and can be changed by increasing or decreasing the approach velocity of the cooling medium. Increased velocity increases the convection coefficient h, thus reducing ΔT.

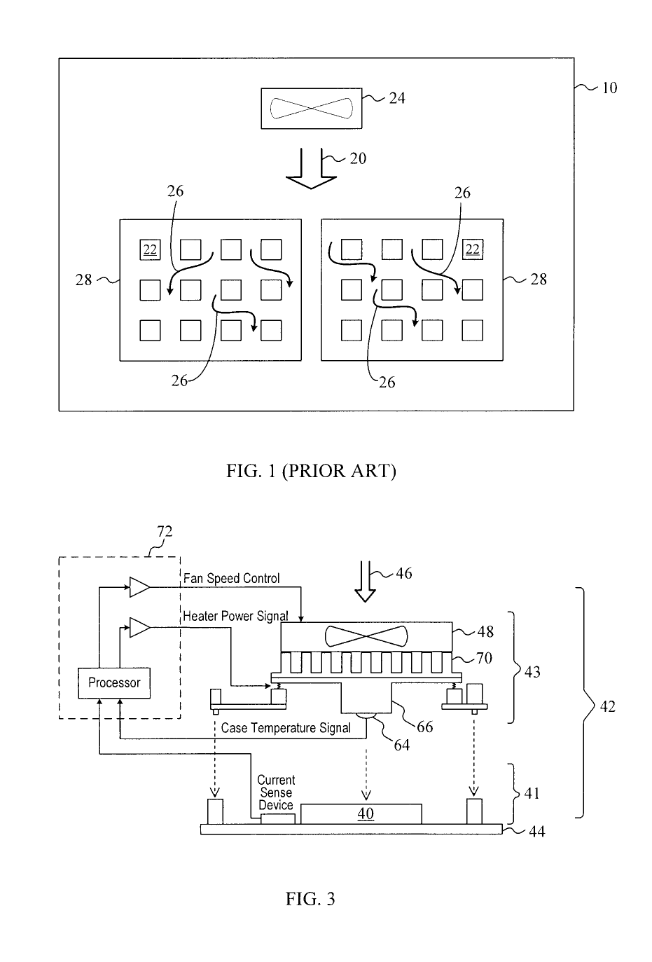

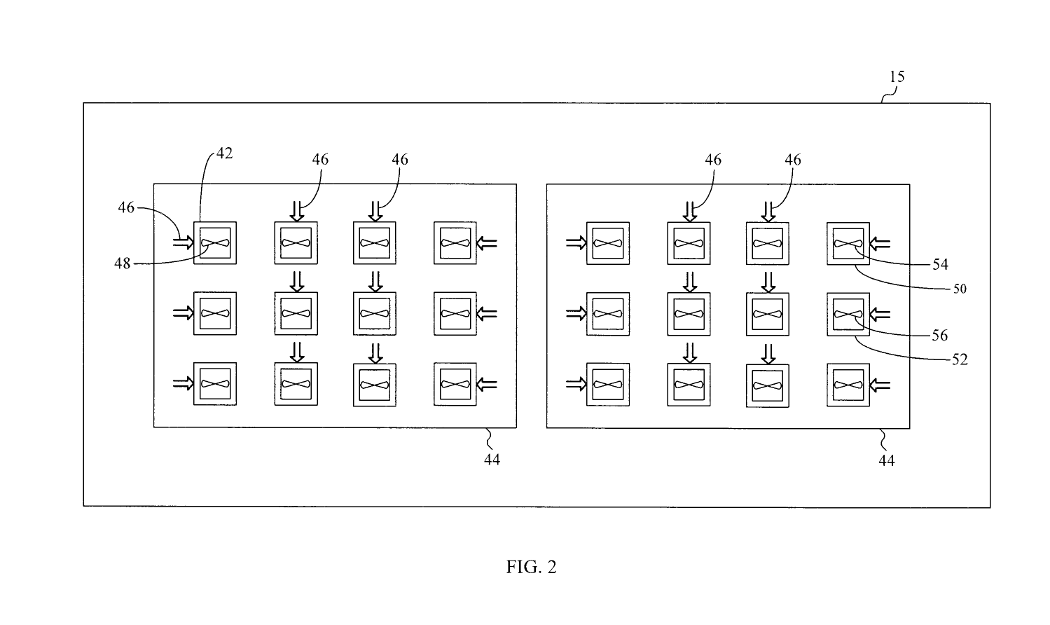

FIG. 2 is a simplified plan view of a system of burn-in boards 44 within a burn-in chamber 15 according to an embodiment of the invention. It should be appreciated that embodiments of the invention may also be practiced without a burn-in chamber. The single source of air flow 20 in FIG. 1 can be replaced by airflow 46 induced at each socket 42 on board 44 by a variable speed-controlled fan 48 mounted on or near each individual socket 42. The air flow 46 from each of the fans 48 is much more uniform with respect to each socket 42 than the unpredictable, non-uniform flow 26 of FIG. 1 because the air flows directly from fan 48 onto the socket 42 without any intervening structures to disrupt the air flow.

The speed of each fan 48 can be individually controlled to respond to the specific heat generation of each IC 40 (see FIG. 3) in each socket 42. The amount of heat generated during burn-in can vary significantly from IC to IC. For example, the IC in socket 50 may be generating more heat than the IC in socket 52. Fan 54 can then be controlled to operate at a higher speed than fan 56 in socket 52 to cool the higher-heat-generating IC in socket 50. In FIG. 1, the single-source cooling method would have resulted in the air flow 20 being increased to a speed that would provide enough convective cooling for socket 50. However, the air flow 20 would also result in over-cooling the IC in socket 52 and causing the temperature of the IC in socket 52 to fall below the desired burn-in temperature range. Thus, in the single-source cooling method of FIG. 1, power is wasted during the testing process by running the fan 24 at a speed higher than required for the IC in socket 52 (and any other lower heat generating ICs) and requiring more power consumption by the individual heater 66 (see FIG. 3) in socket 52 because the IC in socket 52 has been cooled down too much.

FIG. 3 is a side elevation schematic of a socket 42 on a burn-in board 44 according to an embodiment of the invention. The socket 42 shown in FIG. 3 utilizes many of the temperature sensing and control features described and claimed in the '240 patent. Other temperature sensing and control systems, however, can be used with the various embodiments of this invention.

The IC testing socket 42 includes a temperature control apparatus 66 for thermally contacting the IC 40 and directly controlling the temperature of the IC 40 during testing. A temperature sensor 64 in the temperature control apparatus 66 measures the temperature of the top surface of the IC 40. The temperature control apparatus 66 then effects a change in the temperature of the IC 40 by causing conduction of heat to or away from the IC 40. Thus, the temperature control apparatus 66 includes a heater or a cooler.

A heat sink 70 can be mounted in thermal contact with the temperature control apparatus 66. A variable speed fan 48 can be mounted on top of the heat sink 70 to provide individual cooling to the IC 40 in the socket 42. The fan 48 can also be mounted in other positions near the socket 42 as long as the fan 48 is positioned to provide a uniform air flow 46 to the heat sink 70.

The temperature sensed by the sensor 64 can be communicated to a temperature controller 72. Responsive to the signal from the temperature sensor 64, the controller 72 controls the output of the heater 66 and the speed of the variable speed fan 48 to optimize the temperature of the individual IC 40 for testing.

The variable speed fan 48 can be a much lower power-consuming fan than the single source of air flow 20 shown in FIG. 1. The speed of the fan 48 can also be precisely controlled to respond to the specific heat generation of each individual IC 40. Because the convection is being precisely controlled by the fan 48, the temperature of each individual IC 40 can be more accurately controlled to stay within a desired temperature range. Thus, an IC 40 which may not be generating as much heat as another IC is not unnecessarily cooled and does not require unnecessary heating by the heater 66. Consequently, less power is also consumed by heater 66.

While forced air flow has been described as being the convective cooling medium, other cooling media and methods are contemplated to fall within the scope of the invention. Examples of other cooling methods will now be described. The following descriptions are exemplary only and any type of variably controlled cooling method or system is contemplated to be within the scope of the invention.

In another embodiment, airflow may be directed to or away from the IC 40 by means of a mechanical damper or similar device. A damper can limit or increase the airflow to the IC 40 responsive to the specific heat generated by the IC 40.

In another embodiment, a stream of compressed air or other gas can be vented onto the socket 42 to provide convective cooling. The expansion of the compressed air is an adiabatic process that cools the air further without the need of expensive and complicated cooling systems. The cooling effect of the compressed air can be increased even further if the compressed air is chilled prior to venting. The amount of compressed air flow can then be controlled responsive to the heat generation of the IC to optimize the temperature of the IC.

To make the compressed air even more convectively useful, in another embodiment, the solid metal of the heat sink 70 in FIG. 3 can be replaced with a sponge-like thermally conductive material. The sponge-like structure of the thermally conductive material provides an ultra-high amount of surface area per volume of the structure and, thus, provides even higher thermal conductance than a standard finned heat sink.

Using compressed air increases the convective cooling over forced ambient air using a standard fan and is much less expensive than liquid cooling solutions. Further, liquid cooling solutions can leak causing potential damage to the various components and devices under test. No real damage occurs if the compressed air leaks.

Liquid cooling, however, can also be utilized. The amount of cooling liquid flowing in contact with the heat sink can be varied to control the amount of convective cooling. This flow can be controlled responsive to the heat generated by the IC under test. The liquid can be water or any other useful thermally conductive liquid, such as standard refrigerants or even mineral oil.

Yet another cooling method or system can be accomplished using thermoelectric coolers (TECs). TECs can also be variably controlled to provide individual thermoelectric cooling of the socket responsive to the heat generation of the IC under test.

Having described exemplary embodiments of the invention, it should be apparent that modifications and variations can be made by persons skilled in the art in light of the above teachings. Therefore, it is to be understood that changes may be made to embodiments of the invention disclosed that are nevertheless still within the scope of the claims.

1. A system for testing integrated circuit (IC) packages, comprising:
a plurality of IC testing socket bases arranged on a testing board and configured to receive a plurality of IC packages;
a plurality of IC testing socket lids arranged to attach to the testing board, each IC testing socket lid comprising:
a temperature sensor arranged to thermally contact the IC package and measure a surface temperature of the IC package;
a heater or cooler arranged to directly contact the IC package; and
an electronic controller arranged to receive signals from the temperature sensor, wherein the electronic controller is programmed to change the temperature of the heater or cooler responsive to the measured surface temperature of the IC package; and
a plurality of cooling devices arranged to individually remove heat generated by each of the plurality of IC packages, wherein the electronic controller in each IC testing socket lid is further programmed to control a corresponding cooling device to maintain the surface temperature of one of the plurality of IC packages within a desired temperature range.

2. The system of claim 1, wherein each of the plurality of cooling devices is disposed on a corresponding IC testing socket lid.

3. The system of claim 1, wherein each cooling device comprises a variable speed fan and the electronic controller is programmed to adjust the speed of the fan responsive to the heat generated by the IC package.

4. The system of claim 1, wherein each cooling device uses forced air to provide airflow to the IC package.

5. The system of claim 1, wherein each cooling device uses compressed air to provide airflow to the IC package.

6. The system of claim 5, further comprising a chiller arranged to chill the compressed air.

7. The system of claim 1, further comprising a heat sink arranged to thermally contact the heater or cooler.

8. The system of claim 7, wherein the heat sink comprises a sponge-like thermally conductive material.

9. The system of claim 1, wherein each cooling device comprises a thermoelectric cooler.

10. The system of claim 1, further comprising a testing chamber adapted to receive the testing board.

11. A method of controlling the temperature of an integrated circuit (IC) package during one or more of testing, burning-in and programming of the IC package, comprising:
sensing a temperature of the IC package with a temperature sensor in thermal contact with the IC package, the temperature sensor being located in an IC socket lid;
processing data from the temperature sensor in an electronic controller located in the IC socket lid;
controlling the temperature of the IC package with a heater or cooler located in the IC socket lid responsive to a signal from the electronic controller; and
removing heat generated by the IC package to maintain the temperature of the IC package within a desired temperature range with a cooling device.

12. The method of claim 11, wherein the cooling device is located on the IC socket lid.

13. The method of claim 11, wherein the cooling device comprises a variable speed fan.

14. The method of claim 13, wherein removing heat generated by the IC package comprises adjusting the speed of the fan responsive to changes in the sensed temperature of the IC package.

15. A method of independently controlling the temperature of each of a plurality of IC packages during one or more of testing, burning-in and programming the IC packages, comprising:
sensing a temperature of each of the plurality IC packages with a corresponding plurality of temperature sensors, each temperature sensor in thermal contact with a respective IC package;
processing data from the temperature sensors in a plurality of electronic controllers;
controlling the temperature of each IC package with a corresponding heater or cooler responsive to signals from the electronic controllers; and
individually removing heat generated by each IC package to maintain the temperature of each IC package within a desired temperature range with a plurality of cooling devices.

16. The method of claim 15, wherein the plurality of cooling devices comprises variable speed fans.

17. The method of claim 15, wherein individually removing heat generated by each IC package comprises individually adjusting the speed of the fans responsive to changes in the sensed temperature of the corresponding IC package.

18. An IC testing socket lid, comprising:
a temperature sensor arranged to thermally contact the IC package and measure a surface temperature of the IC package;
a heater or cooler arranged to directly contact the IC package;
an electronic controller arranged to receive signals from the temperature sensor, wherein the electronic controller is programmed to change the temperature of the heater or cooler responsive to the measured surface temperature of the IC package; and
a cooling device arranged to remove heat generated by the IC package, wherein the electronic controller is further programmed to control the cooling device to maintain the surface temperature of the IC package within a desired temperature range.

19. The IC testing socket lid of claim 18, wherein the cooling device comprises a variable speed fan and the electronic controller is programmed to adjust the speed of the fan responsive to the heat generated by the IC package.

20. The IC testing socket lid of claim 18, wherein the cooling device uses forced air to provide airflow to the IC package.
